(19) United States
(12) Patent Application Publication
(10) Pub. No.: US 2014/0300365 A1
(43) Pub. Date: Oct. 9, 2014

(54) DIAGNOSIS METHOD AND DIAGNOSIS APPARATUS FOR DETERMINING A CURRENT CAPACITY OF A BATTERY CELL IN A HANDHELD MACHINE TOOL

(71) Applicants: Bernd Ziegler, Hiltenfingen (DE); Thomas Mueller, Klosterlechfeld (DE)

(72) Inventors: Bernd Ziegler, Hiltenfingen (DE); Thomas Mueller, Klosterlechfeld (DE)

(73) Assignee: Hilti Aktiengesellschaft, Scheaan (LI)

(21) Appl. No.: 14/241,765

(22) PCT Filed: Jun. 20, 2012
(86) PCT No.: PCT/EP2012/061772

§ 371 Date: Apr. 16, 2014

(30) Foreign Application Priority Data
Aug. 30, 2011 (DE) 102011081800.6

(51) Int. Cl. G01R 31/36

(52) U.S. Cl. CPC G01R 31/362
USPC 324/427

(57) ABSTRACT

A method for determining the momentary capacity of a battery cell of a handheld power tool, including the following steps: measuring a first open-circuit voltage of the battery cell; determining the state of charge of the battery cell at the measured first open-circuit voltage as a function of a predetermined ratio of the open-circuit voltage to the state of charge of the battery cell; changing the charge stored in the battery cell in order to provide a changed state of charge; measuring a second open-circuit voltage at an actual value of the changed state of charge, and calculating the momentary capacity of the battery cell as a function of a nominal capacity of the battery cell, as a function of a target value of the changed state of charge, and as a function of the measured second open-circuit voltage.

The present invention relates to a diagnostic method and to a diagnostic device for determining the momentary capacity of a battery cell for a battery-operated handheld power tool, and it also relates to a battery-operated handheld power tool, especially an electric handheld power tool such as, for example, an electric screwdriver, a handheld power drill.

### BACKGROUND

In the conventional diagnosis of a battery cell such as, for instance, a rechargeable battery or an accumulator, the battery cell is completely charged and subsequently completely discharged in order to determine the momentary capacity. Therefore, conventional methods for diagnosing battery cells require at least a complete charging and subsequent discharging of the battery. In this context, the maximum possible charging current as well as the maximum possible discharging current are limited by the battery cell. This translates into a time-consuming procedure for diagnosing the battery cell.

Here, a value of about 1 C (simple, one-hour charging current) is typical, whereby the battery cell is charged within one hour. The discharging can be regularly carried out at a multiple of 1 C, whereby the discharging time is shortened accordingly. At 4 C, for instance, the battery cell is discharged within 15 minutes. All in all, these conventional methods can give rise to a diagnosis time of more than one hour. High charging and discharging currents of, for example, more than 1 C, are normally avoided since they cause the battery to age prematurely.

Moreover, a disadvantage is the need for complex power electronics that are designed to appropriately charge and discharge the battery cell.

### SUMMARY OF THE INVENTION

The method according to the present invention for determining the momentary capacity of a battery cell of a handheld power tool encompasses the following steps: measuring a first open-circuit voltage of the battery cell; determining the state of charge of the battery cell at the measured first open-circuit voltage as a function of a predetermined ratio of the open-circuit voltage to the state of charge of the battery cell; changing the charge stored in the battery cell in order to provide a changed state of charge; measuring a second open-circuit voltage at an actual value of the changed state of charge, and calculating the momentary capacity of the battery cell as a function of a nominal capacity of the battery cell, as a function of a target value of the changed state of charge, said target value having been determined on the basis of the determined state of charge, and as a function of the measured second open-circuit voltage.

The target value of the changed state of charge is especially determined as a function of the determined state of charge at the measured first open-circuit voltage and at the degree of change of the charge stored in the battery cell.

According to the invention, it is not necessary to completely charge and to subsequently completely discharge the battery cell in order to determine its momentary capacity. This reduces or minimizes the time needed to determine the momentary capacity. As a result, the diagnosis time is reduced to a minimum according to the invention. Here, diagnosis times of less than five minutes are possible.

Moreover, according to the invention, there is no need for the conventional use of complex power electronics. For instance, discharging takes place via the usual consumers of the handheld power tool, for example, via the motor of the handheld power tool. In particular, for this purpose, the handheld power tool can be switched on for a predetermined period of time, for instance, one minute. This markedly reduces the technical resources needed by the present invention in comparison to conventional diagnostic methods.

In one embodiment, a target open-circuit voltage is determined at a target value of the changed state of charge as a function of the predetermined ratio. Then the momentary capacity of the battery cell can be calculated as a function of the nominal capacity of the battery cell, as a function of the determined target open-circuit voltage and as a function of the measured second open-circuit voltage.

In another embodiment, the calculated momentary capacity is stored in a memory associated with the battery cell or with the handheld power tool. The memory, for example, an EEPROM, is suitable for storing information.

In another embodiment, the calculated momentary capacity is provided by means of the memory to at least one device that has been authenticated vis-à-vis the battery cell.

The authenticated device is, for instance, a receiving device associated with the user of the handheld power tool or a receiving device associated with a customer service.

In another embodiment, the charge stored in the battery cell is changed by discharging the battery cell or by charging the battery cell.

In this context, the charge of the battery cell is changed by a charge quantity that, at the maximum, amounts to 10% of the nominal capacity of the battery cell.

In another embodiment, the predetermined ratio of the open-circuit voltage to the state of charge of the battery cell is provided by measuring the battery cell prior to its use in the handheld power tool.

Consequently, prior to being used in the handheld power tool, the battery cell is measured in order to generate the predetermined ratio of the open-circuit voltage to the state of charge. The momentary capacity can be determined every time as a function of this predetermined ratio, which is valid during the entire operating time of the battery cell.

In another embodiment, the predetermined ratio of the open-circuit voltage (y), expressed in volts, to the state of charge (x), expressed as a percentage, of the battery cell is a polynomial of the n^{th} order, wherein n=3 or n=5. For example, for n=5: y=ax⁵+bx⁴+cx³+dx²+ex+f.

In the case of a lithium-ion battery with five cells and a nominal capacity of 2240 mAh, the following polynomial is obtained: y=(2E−09)x⁵−(5E−07)x⁴+(6E−05)x³−0029x²+0.0777x+13.589.

In another embodiment, the predetermined ratio of the open-circuit voltage to the state of charge of the battery cell is stored in a look-up table (LUT) that is stored in a memory that is associated with the battery cell or with the handheld power tool.

In yet another embodiment, the equation

$${C}_{momentary} = {C}_{new} \cdot \frac{Δ {U}_{target}}{Δ {U}_{actual}}$$

is employed for purposes of calculating the momentary capacity. C_{momentary}, refers to the momentary capacity of the battery cell. C_{new} refers to the nominal capacity of the battery cell. ΔU_{target} refers to the voltage differential between the measured first open-circuit voltage OCV1 and the determined target open-circuit voltage U_{target}. ΔU_{actual} refers to the voltage differential between the measured first open-circuit voltage OCV1 and the measured second open-circuit voltage OCV2.

In another embodiment, the equation

$${C}_{momentary} = {C}_{new} \cdot \frac{Δ {C}_{actual}}{Δ {C}_{target}}$$

is employed for purposes of calculating the momentary capacity. C_{momentary} refers to the momentary capacity of the battery cell. C_{new} refers to the nominal capacity of the battery cell. ΔC_{target} refers to the difference between the state of charge SOC1 of the battery cell at the measured first open-circuit voltage OCV1 and the target value C_{target} of the changed state of charge. ΔC_{actual} refers to the difference between the state of charge SOC1 of the battery cell at the measured first open-circuit voltage OCV1 and the actual value C_{actual} of the changed state of charge.

In another embodiment, the actual value C_{actual} of the changed state of charge at the measured second open-circuit voltage OCV2 is determined as a function of the predetermined ratio.

Consequently, the equation above can also be formulated as follows:

$${C}_{momentary} = {C}_{new} \cdot \frac{Δ {C}_{actual}}{Δ {C}_{target}} = {C}_{new} \cdot \frac{SOC 1 - {C}_{actual}}{SOC 1 - {C}_{target}}$$

In another embodiment, the actual value C_{actual} of the changed state of charge at the measured second open-circuit voltage OCV2 is determined as a function of the charge quantity Q by which the charge stored in the battery cell is changed.

$$Δ {C}_{actual} = \frac{Q}{Δ {U}_{actual}} = \frac{Q}{OCV 1 - OCV 2}$$

In this context, the current, for example, in the battery charger, is measured during the change of the state of charge and integrated in the microcontroller of the battery charger. This yields the charge quantity Q by which the charge stored in the battery cell is changed. In this case, the following equation can be employed to calculate the momentary capacity of the battery cell:

$${C}_{momentary} = \frac{{C}_{new}}{Δ {C}_{target}} = \frac{Q}{OCV 1 - OCV 2}$$

In this embodiment as well, there are two ways to change the stored charge in the battery cell in order to provide the changed state of charge, namely, charging and thus diagnosis during the charging procedure, or else discharging and thus diagnosis during the discharging procedure. Examples of the diagnosis during the charging procedure and of the diagnosis during the discharging procedure will be given below:

Diagnosis during the charging procedure

The predetermined ratio of the open-circuit voltage OCV to the state of charge SOC is stored in the memory of the battery cell. Prior to the start of the charging procedure, the microcontroller of the battery cell measures the momentary open-circuit voltage OCV1. The ascertained OCV1 value is stored in the memory of the microcontroller. On the basis of the table, the state of charge SOC1 of the battery cell associated with the open-circuit voltage OCV1 is ascertained. In this context, it is assumed that the ratio of SOC to OCV is not dependent on the capacity. During the charging procedure, the current, for example, in the battery charger, is measured and integrated in the microcontroller of the battery charger. The charged capacity ΔC_{actual} is results from the difference between the state of charge SOC1 of the battery cell at the first open-circuit voltage OCV1 and the actual value C_{actual} of the changed state of charge. After the charging procedure, the battery charger sends the ΔC_{actual} value to the microcontroller of the battery cell. After the charging procedure has been completed, the microcontroller of the battery cell measures the open-circuit voltage OCV2. Once the OCV2 value no longer changes, the appertaining state of charge SOC2 of the battery cell at this second open-circuit voltage OCV2 is ascertained.

The following algorithm can be employed for purposes of determining the momentary capacity C_{momentary}:

$$\begin{matrix}Δ {C}_{target} = {C}_{new} \cdot ( SOC 2 - SOC 1 ) & ( 1 ) \\ SOH = \frac{Δ {C}_{actual}}{Δ {C}_{target}} & ( 2 ) \\ {C}_{momentary} = SOH \cdot {C}_{new} & ( 3 )\end{matrix}$$

SOH and C_{momentary} can be stored in the memory. Particularly when a completed charging procedure is carried out with a charging start at SOC<5% and a charging end at SOC>95%, the actually charged ΔC_{actual} value can be additionally stored in the memory of battery cell.

Diagnosis during the discharging procedure

The table containing the predetermined ratio of the open-circuit voltage OCV to the state of charge SOC are stored in the memory of the battery cell. When the battery is discharged for the first time after a charging procedure, the microcontroller of the battery cell measures the momentary open-circuit voltage OCV1. The ascertained OCV1 value is stored in the memory of the microcontroller. During the discharging procedure, the current in the handheld power tool is measured and integrated in the microcontroller of the handheld power tool. This value corresponds to ΔC_{actual}. After each discharging procedure, the ΔC_{actual} value can be transmitted to the microcontroller of the battery cell and stored in its memory. In each case, the ΔC_{actual} value transmitted by the handheld power tool is added to the C_{actual} value that is already present, and this is stored in the memory.

The following algorithm can be employed for purposes of determining the momentary capacity:

$$\begin{matrix}Δ {C}_{target} = {C}_{new} \cdot ( SOC 1 - SOC 2 ) & ( 4 ) \\ SOH = \frac{Δ {C}_{actual}}{Δ {C}_{target}} & ( 5 ) \\ {C}_{momentary} = SOH \cdot {C}_{new} & ( 6 )\end{matrix}$$

In another embodiment, in order to stabilize the state of charge of the battery cell, there is a predetermined time period between changing the charge stored in the battery cell and measuring the second open-circuit voltage.

### BRIEF DESCRIPTION OF THE DRAWINGS

The description below explains the invention on the basis of embodiments and figures provided by way of examples. The figures show the following:

FIG. 1: a schematic flow chart of a method for determining the momentary capacity of a battery cell of a handheld power tool;

FIG. 2: a diagram that depicts the open-circuit voltage of a battery cell as a function of its state of charge;

FIG. 3: a table for storing the predetermined ratio of the open-circuit voltage to the state of charge of the battery cell;

FIG. 4: an electric screwdriver; and

FIG. 5: a battery charger for an electric screwdriver.

Unless otherwise indicated, identical or functionally equivalent elements are designated in the figures by the same reference numerals.

### DETAILED DESCRIPTION

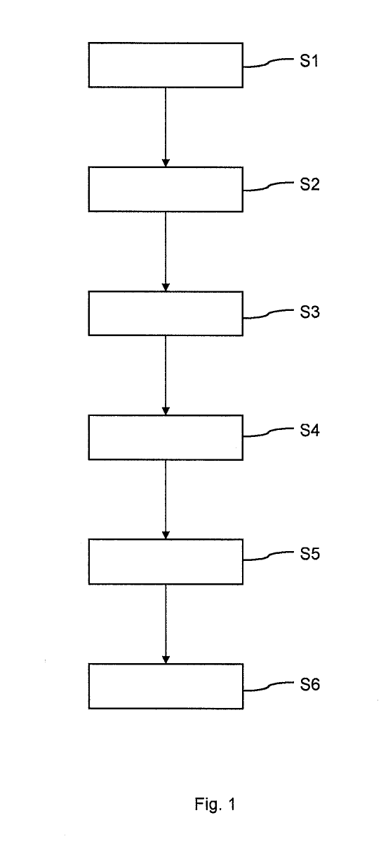

FIG. 1 shows a schematic flow chart of a method for determining the momentary capacity of a battery cell of a handheld power tool. The battery cell 11 is, for instance, a rechargeable battery, especially a battery pack 10. The handheld power tool is, for example, an electric screwdriver.

In step S1, an open-circuit voltage OCV1 of the battery cell 11 is measured.

In step S2, the state of charge SOC1 of the battery cell 11 at the measured first open-circuit voltage OCV1 is determined. The predetermined ratio of the open-circuit voltage OCV to the state of charge SOC of the battery cell is used for this determination. The predetermined ratio of the open-circuit voltage OCV to the state of charge SOC is generated by measuring the battery cell 11 prior to its use in the handheld power tool 1. This predetermined ratio is stored in a look-up table that is stored in a memory 26 associated with the battery cell or the handheld power tool.

The applicant has ascertained that the ratio of the open-circuit voltage OCV to the state of charge SOC of the battery cell remains essentially the same over its service life and is thus predetermined.

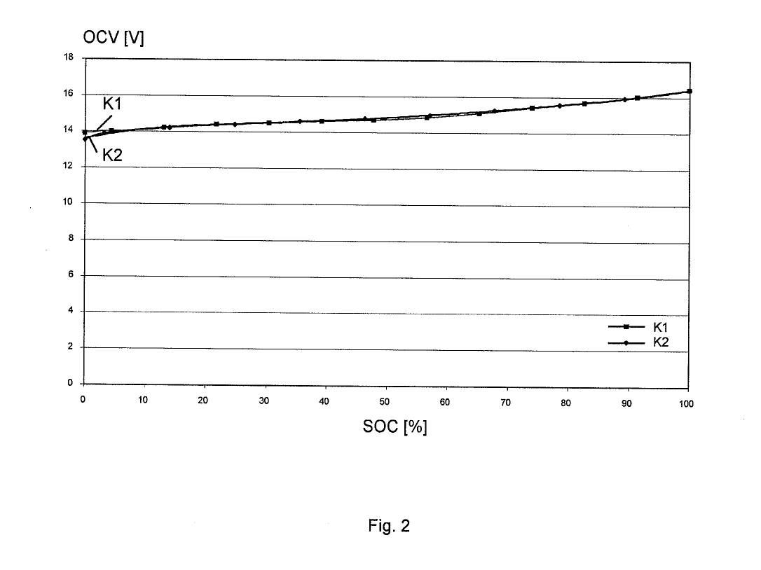

In this regard, FIG. 2 shows a diagram that depicts the open-circuit voltage OCV of a battery cell as a function of its state of charge SOC. FIG. 2 depicts two curves K1 and K2. Curve K1 shows the open-circuit voltage OCV of a new battery cell, whereas curve K2 shows the open-circuit voltage OCV after 950 charging cycles. All in all, FIG. 2 illustrates that the curves K1 and K2—except for the negligible area in which the SOC is below 5%—coincide or at least largely coincide, and thus the ratio of the open-circuit voltage OCV to the state of charge SOC is predetermined.

In step S3, the charge stored in the battery cell 11 is changed for purposes of providing a changed state of charge. The battery cell 11 can be charged or discharged in order to change the stored charge.

In step S4, the target open-circuit voltage U_{target} at a target value C_{target} of the changed state of charge is determined as a function of the predetermined ratio.

In step S5, a second open-circuit voltage OCV2 at an actual value C_{actual} of the changed state of charge is measured.

In step S6, the momentary capacity C_{momentary} of the battery cell is calculated as a function of a nominal capacity C_{new} of the battery cell, as a function of the determined target open-circuit voltage U_{target} and as a function of the measured second open-circuit voltage OCV2. The calculated momentary capacity C_{momentary} can be stored in a memory associated with the battery cell or with the handheld power tool. The calculated momentary capacity C_{momentary} is provided by means of this memory to at least one device that has been authenticated vis-à-vis the battery cell.

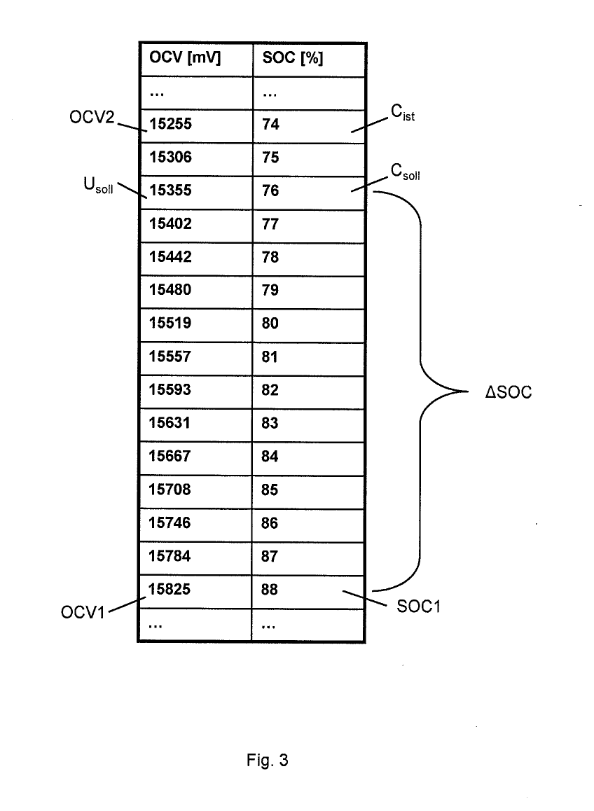

An example of the calculation of the momentary capacity C_{momentary} is given below making reference to FIG. 3, In this context, FIG. 3 shows a table for storing the predetermined ratio of the open-circuit voltage OCV to the state of charge SOC of the battery cell of a Panasonic B144 battery.

The B144 battery has a nominal capacity of 2240 mAh (C_{new}=2240 mAh).

In step S1, the first the open-circuit voltage OCV1 is measured (OCV1=15825 mV). In step 2, the table of FIG. 3 is employed to ascertain the state of charge SOC1 at the first open-circuit voltage OCV1 (SOC1=88%). In step S3, the state of charge of the B144 battery is changed in that it is discharged (ΔSOC=12%). Thus, the target value C_{target} of the changed state of charge is obtained from C_{target}=SOC1−ΔSOC=88%−12%=76%.

In step S4, the target open-circuit voltage U_{target} at the target value C_{target} of the changed state of charge is determined on the basis of the table from FIG. 3 (U_{target}=15355 mV). Subsequently, the second open-circuit voltage OCV2 at the a priori unknown actual value of the changed state of charge is measured (OCV2=15255 mV).

Consequently, C_{momentary} results as follows:

$${C}_{momentary} = {C}_{new} \cdot \frac{Δ {U}_{target}}{Δ {U}_{actual}} = {C}_{new} \cdot \frac{OCV 1 - {U}_{target}}{OCV 1 - OCV 2} = 2240 mAh \cdot \frac{15825 mV - 15355 mV}{15825 mV - 15255 mV} = 1847 mAh$$

At C_{momentary}=1847 mAh, an actual value C_{momentary} of the changed state of charge of 74% (C_{momentary}=74%) is obtained.

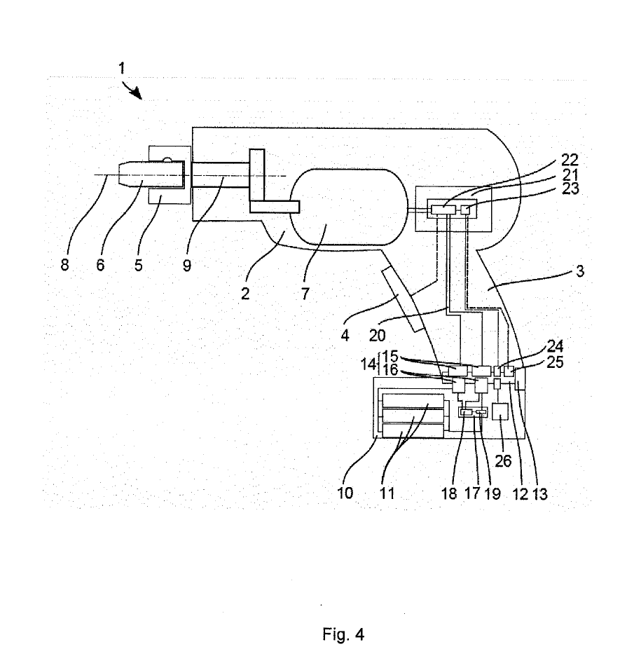

FIG. 4 shows an electric screwdriver 1 as an example of a handheld power tool. The electric screwdriver 1 has housing 2 with a handle 3 by means of which a user can hold and guide the electric screwdriver 1. A pushbutton 4 on the handle 3 allows the user to operate the electric screwdriver 1. Typically, the user has to continuously hold the pushbutton 4 depressed in order to keep the electric screwdriver 1 in operation.

The electric screwdriver 1 has a tool socket 5 into which the user can insert a screwdriver bit 6. When the pushbutton 4 is actuated, an electric motor 7 turns the tool socket 5 around its axis 8. The electric motor 7 is coupled to the tool socket 5 via a spindle 9 and optionally by other components of a drive train, e.g. clutch, gears.

The electric motor 7 is supplied with current by means of a battery cell 11. The battery cell is, for instance, part of a battery pack 10. The battery pack 10 especially has a plurality of secondary battery cells 11 which are based on lithium chemistry.

The housing 2 has a holder 12 for the battery pack 10 which is arranged, for example, on one end of the handle 3. The holder 12 can have rails with an L-shaped profile into which complementary rails on the battery pack 10 can be slid and inserted. A detachable locking element 13 prevents the battery pack 10 from falling out of the holder 12. A power connector 14 of the handheld power tool 1 is arranged in the holder 12. The power connector 14 comprises, for example, two or more electric contacts 15. The battery pack 10 has contacts 16 that are complementary to the power connector 14 of the handheld power tool 1 and that make electrical contact when a battery pack 10 has been inserted into the holder 12.

The battery pack 10 can have an autonomous protection mechanism 17. The protection mechanism 17 comprises, for instance, a voltage sensor 18 that monitors the voltages of the individual battery cells 11. Whenever the protection mechanism 17 detects a drop in the voltage of one of the battery cells 11 below a critical threshold value, the current output of the battery pack 10 is interrupted. The critical threshold value is selected in such a way that an irreversible discharging of the battery cells 11 is prevented. The threshold value, for instance, of batteries 11 that are based on lithium-ion chemistry is approximately 2.5 V, especially at room temperature. The battery pack 10 can interrupt a current path 20 between the battery pack 10 and the electric motor 7, for example, by means of a switch 19, e.g. a FET in the battery pack 10 or in the handheld power tool 1. The reversible protection mechanism 17 and the associated switch 19 are independent of other systems. With an arrangement of the switch 19 in the battery pack 10, this is particularly the case when the power supply to the handheld power tool 1 by means of the battery pack 10 is completely interrupted.

The handheld power tool 1 also has a motor control unit 21 that has one or more switching elements 22 and that sets the power consumption of the handheld power tool 1 in order to regulate the rotational speed to the target value. Moreover, the handheld power tool 1 has a soft starter 23.

The motor control unit 21 communicates with the battery pack 10 in order to ascertain its properties. A communication interface 24 of the motor control unit 21 queries, among other things, the inner resistance of the battery pack 19.

The communication interface 24 is preferably an electric communication interface whose receiving unit receives from the battery pack 10 information units that are transmitted as electric signals from a memory module 26. The memory module 26 stores the ratio of the open-circuit voltage to the state of charge of the battery cell 11. The motor control unit 21 is configured to carry out the method according to FIG. 1 and thus to diagnose the battery pack 10. Moreover, the handheld power tool 1 can have a temperature sensor 25.

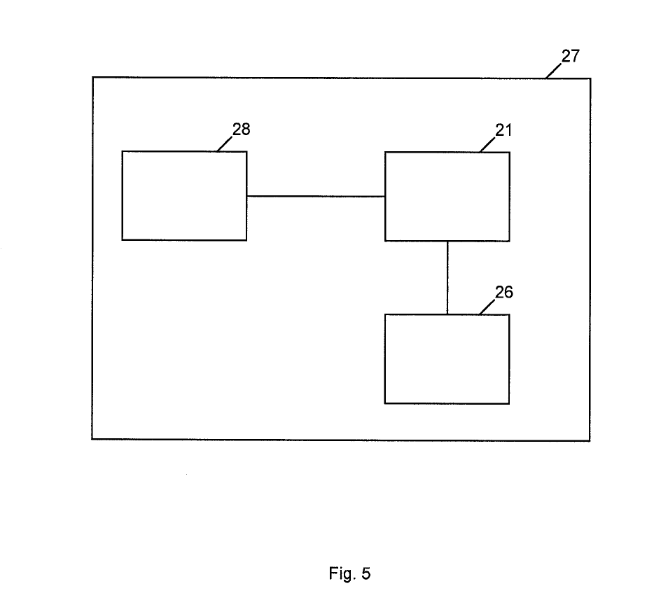

FIG. 5 shows a battery charger 27 for an electric screwdriver 1. The electric screwdriver 1 is shown by way of an example in FIG. 4. The battery charger 27 has a dock to accommodate the battery pack 10 of the electric screwdriver 1 during the charging procedure. The battery charger 27 also has a device 21 to diagnose the battery cells 11 of the battery pack 10. The device 21 is especially configured to carry out the method according to FIG. 1. Moreover, the battery charger 27 has a memory module 26 that stores the ratio of the open-circuit voltage OCV to the state of charge SOC of the battery cell 11.

Glossary

C_{momentary} momentary capacity of the battery cell

C_{actual} actual value of the changed state of charge

ΔC_{actual} difference between the state of charge of the battery cell at the measured first open-circuit voltage and the actual value of the changed state of charge

C_{new} nominal capacity of the battery cell

C_{target} target value of the changed state of charge

ΔC_{target} difference between the state of charge of the battery cell at the measured first open-circuit voltage and the target value of the changed state of charge

OCV1 first open-circuit voltage

OCV2 second open-circuit voltage

Q charge quantity

SOC1 state of charge of the battery cell at the first open-circuit voltage

SOC2 state of charge of the battery cell at the second open-circuit voltage

SOH momentary state of health of the battery cell

ΔU_{target} differential voltage between the measured first open-circuit voltage and the determined target open-circuit voltage

ΔU_{actual} differential voltage between the measured first open-circuit voltage and the measured second open-circuit voltage

Uₘₑₐₛ₂ measured second open-circuit voltage at the actual value of the changed state of charge

U_{target} target open-circuit voltage at the actual value of the changed state of charge

1-16. (canceled)

17. A method for determining a momentary capacity of a battery cell of a handheld power tool, the method comprising the following steps:
measuring a first open-circuit voltage of the battery cell;
determining a first state of charge of the battery cell at the measured first open-circuit voltage as a function of a predetermined ratio of an open-circuit voltage to a state of charge of the battery cell;
changing the charge stored in the battery cell in order to provide a changed state of charge;
measuring a second open-circuit voltage at an actual value of the changed state of charge; and
calculating the momentary capacity of the battery cell as a function of a nominal capacity of the battery cell, as a function of a target value of the changed state of charge, the target value having been determined on the basis of the determined first state of charge, and as a function of the measured second open-circuit voltage.

18. The method as recited in claim 17 wherein a target open-circuit voltage is determined at the target value of the changed state of charge as a function of the predetermined ratio, and the momentary capacity of the battery cell is calculated as a function of the nominal capacity of the battery cell as a function of the determined target open-circuit voltage and as a function of the measured second open-circuit voltage.

19. The method as recited in claim 17 wherein the calculated momentary capacity is stored in a memory associated with the battery cell or with the handheld power tool.

20. The method as recited in claim 19 wherein the calculated momentary capacity is provided via the memory to at least one device authenticated vis-à-vis the battery cell.

21. The method as recited in claim 17 wherein the changing step includes changing the charge stored in the battery cell by discharging the battery cell or by charging the battery cell.

22. The method as recited in claim 21 wherein the charge stored in the battery cell is changed by discharging the battery cell or by charging the battery cell by a charge quantity, at the maximum, amounting to 10% of the nominal capacity of the battery cell.

23. The method as recited in claim 17 wherein the predetermined ratio of the open-circuit voltage to the state of charge of the battery cell is provided by measuring the battery cell prior to use in the handheld power tool.

24. The method as recited in claim 17 wherein the predetermined ratio of the open-circuit voltage to the state of charge of the battery cell is a polynomial of the nth order, wherein n=3 or n=5.

25. The method as recited in claim 17 wherein the predetermined ratio of the open-circuit voltage to the state of charge of the battery cell is stored in a look-up table stored in a memory associated with the battery cell or with the handheld power tool.

26. The method as recited in claim 17 wherein the equation
$${C}_{momentary} = {C}_{new} \cdot \frac{Δ {U}_{target}}{Δ {U}_{actual}}$$
is employed for purposes of calculating the momentary capacity, wherein C_{momentary} refers to the momentary capacity of the battery cell, C_{new} refers to the nominal capacity of the battery cell, ΔU_{target} refers to the voltage differential between the measured first open-circuit voltage and the determined target open-circuit voltage, and ΔU_{actual} refers to the voltage differential between the measured first open-circuit voltage and the measured second open-circuit voltage.

27. The method as recited in claim 17 wherein the equation
$${C}_{momentary} = {C}_{new} \cdot \frac{Δ {C}_{actual}}{Δ {C}_{target}}$$
is employed for purposes of calculating the momentary capacity, wherein C_{momentary} refers to the momentary capacity of the battery cell, C_{new} refers to the nominal capacity of the battery cell, ΔC_{target} refers to the difference between the state of charge of the battery cell at the measured first open-circuit voltage and the target value of the changed state of charge, and ΔC_{actual} refers to the difference between the state of charge of the battery cell at the measured first open-circuit voltage and the actual value of the changed state of charge.

28. The method as recited in claim 27 wherein the actual value of the changed state of charge at the measured second open-circuit voltage is determined as a function of the predetermined ratio or as a function of a charge quantity, the charge quantity being an amount of charge changed during the changing step.

29. The method as recited in claim 17 wherein, in order to stabilize a state of charge of the battery cell, at least a predetermined time period between the changing step and the measuring of the second open-circuit voltage exists.

30. A device for diagnosing a battery cell of a handheld power tool configured to execute the method steps as recited in claim 17.

31. A handheld power tool comprising the device for diagnosing a battery cell of the handheld power tool as recited in claim 30.

32. A battery charger for a battery cell of a handheld power tool comprising the device for diagnosing the battery cell of the handheld power tool as recited in claim 30.
